(19) United States
(12) Patent Application Publication
(10) Pub. No.: US 2008/0160170 A1
(43) Pub. Date: Jul. 3, 2008

(54) TECHNIQUE FOR USING AN IMPROVED SHIELD RING IN PLASMA-BASED ION IMPLANTATION

(75) Inventors: Timothy Miller, Ipswich, MA (US); Edmund J. Winder, Kirkland, WA (US); Richard J. Hetel, Boxford, MA (US); Harold M. Persing, Westbrook, ME (US); Vikram Singh, North Andover, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Assoicates, Inc., Gloucester, MA (US)

(21) Appl. No.: 11/617,348

(22) Filed: Dec. 28, 2006

(51) Int. Cl. C23C 14/02; B05C 11/00

(52) U.S. Cl. 427/8; 118/712; 427/444

(57) ABSTRACT

A technique for using an improved shield ring in plasma-based ion implantation is disclosed. In one particular exemplary embodiment, the technique may be realized as an apparatus and method for plasma-based ion implantation, such as radio frequency plasma doping (RF-PLAD). The apparatus and method may comprise a shield ring positioned on a same plane as and around a periphery of a target wafer, wherein the shield ring comprises an aperture-defining device for defining an area of at least one aperture, a Faraday cup positioned under the at least one aperture, and dose count electronics connected the Faraday cup for calculating ion dose rate. The at least one aperture may comprise at least one of a circular, arc-shaped, slit-shaped, ring-shaped, rectangular, triangular, and elliptical shape. The aperture-defining device may comprise at least one of silicon, silicon carbide, carbon, and graphite.

### FIELD OF THE DISCLOSURE

The present disclosure relates generally to plasma-based ion implantation and, more particularly, to a technique for using an improved shield ring in plasma-based ion implantation.

### BACKGROUND OF THE DISCLOSURE

Ion implantation is a process of depositing chemical species into a substrate by direct bombardment of the substrate with energized ions. In semiconductor fabrication, ion implanters are used primarily for doping processes that alter the type and level of conductivity of target materials. A precise doping profile in an integrated circuit (IC) substrate and its thin-film structure is often crucial for proper IC performance. To achieve a desired doping profile, one or more ion species may be implanted in different doses and at different energy levels. A specification of the ion species, doses, and energies is referred to as an ion implantation recipe.

In conventional ion implantation, ions are extracted from a plasma source and are typically filtered (e.g., for mass, charge, energy, etc.), accelerated and/or decelerated, and collimated through several electro-static/dynamic lenses before being directed to a substrate. By contrast, in plasma-based ion implantation, a substrate is immersed in plasma. A negative voltage is applied to the substrate and ions are extracted through a subsequent sheath between the substrate and plasma.

Several types of plasma sources exist, such as capacitively-coupled plasmas (CCPs), inductively-coupled plasmas (ICPs), glow discharges (GD), and hollow cathode (HC), to name a few. Of these examples, ICPs are typically better suited for ion implantation because of lower electron temperature and higher electron density when compared to CCPs. An example of an ICP is radio frequency (RF) plasma.

A cross-sectional view of a typical radio frequency plasma doping system (RF-PLAD) 100 is depicted in FIG. 1. The plasma doping system 100 includes a plasma chamber 102 and a chamber top 104. The chamber top 104 includes a conductive top section 116, a first section 106, and second section 108. The top section 116 has a gas entry port 118 for a process gas to enter. Once the process gas enters the gas entry port 118 of the top section 116, it flows on top of a baffle 126 before being evenly distributed in the chamber 102. The first section 106 of the chamber top 104 extends generally in a horizontal direction. The second section 108 of the chamber top 104 extends from the first section 106 in generally a vertical direction. A helical coil antenna 112 having a plurality of turns wraps around the second section 108. A planar coil antenna 114 having a plurality of turns typically sits on the first section 106 and surrounds the second section 108. The first and second sections 106, 108 are typically formed of a dielectric material 110 for transferring RF power to the plasma inside the chamber 102.

An RF source 130, e.g., an RF power supply, may be electrically connected to at least one of the helical coil antenna 112 and the planar coil antenna 114 by an impedance matching network 132 that maximizes power transferred from the RF source 130 to the RF antennas 112, 114. When the RF source 130 resonates RF currents in the RF antennas 112, 114, the RF antennas 112, 114 induce RF current into the chamber 102 to excite and ionize process gas for generating a plasma in the chamber 102.

The geometry of the first and second sections 106, 108 of the chamber top 104 and the configuration of the RF antennas 112, 114 are chosen so that a uniform plasma is generated. In addition, electromagnetic coupling may be adjusted with a coil adjuster 134 to improve uniformity of generated plasma.

A platen (or E-clamp) 124 is positioned in the chamber 102 below the baffle 126. The baffle 126 may be grounded or floating. A target wafer 120 is positioned on a surface of the platen 124, which may be biased by a voltage power supply 128, so that ions in generated plasma are attracted to the target wafer 120.

A shield ring 144, which may be in the shape of an annulus, is positioned on a same plane as and around a periphery of the target wafer 120. The shield ring 144 is typically formed of a solid material, i.e., aluminum, and may have one or more apertures 146 that define an area. One or more Faraday cups 140 may be positioned on a plane below the target wafer 120, under the one or more apertures 146 of the shield ring 144 and adjacent to the platen 124.

Measurement of ion dose rate in the plasma doping system 100 may be accomplished using the one or more Faraday cups 140. Incident ion flux may be measured by the one or more Faraday cups 140 as an electrical current. The ion dose rate of the target wafer 120 may be calculated by dose count electronics (DCE) 142 by taking the measured electrical current and dividing by the area of shield ring apertures 146 above the one or more Faraday cups 140. As a result, the area of shield ring apertures 146 is a critical parameter in calculating ion dose rate.

However, the area of shield ring apertures 146 is subject to change over time. One reason for such a change, for example, may be attributed to deterioration (or etching) by NF₃ plasma exposure during plasma doping (PLAD) operation. An NF₃ cleaning process is periodically used to maintain satisfactory process control conditions within the chamber 102. However, this often results in an undesired effect of etching the material of the shield ring 144 and, consequently, enlarging the area of the one or more shield ring apertures 146.

When the one or more shield ring apertures 146 reach a certain enlarged size, e.g., where the area of the one or more shield ring apertures 146 is larger than an opening area of the one or more Faraday cups 140, the one or more Faraday cups 140 may become saturated with too much signal (or current), causing the dose count electronics (DCE) 142 to calculate an inaccurate ion dose rate.

Frequently replacing the shield ring 144 in order to maintain a well-defined area for the one or more shield ring apertures 146 may provide a temporary solution. However, the process for replacing shield rings is often expensive, inconvenient, and tedious.

In view of the foregoing, it would be desirable to provide a technique for using an improved shield ring in plasma-based ion implantation to overcome the above-described inadequacies and shortcomings.

### SUMMARY OF THE DISCLOSURE

A technique for using an improved shield ring in plasma-based ion implantation is disclosed. In accordance with one particular exemplary embodiment, the technique may be realized as an apparatus for plasma-based ion implantation. The apparatus may comprise a shield ring positioned on a same plane as and around a periphery of a target wafer, wherein the shield ring comprises an aperture-defining device for defining an area of at least one aperture, a Faraday cup positioned under the at least one aperture, and dose count electronics connected the Faraday cup for calculating ion dose rate.

In accordance with other aspects of this particular exemplary embodiment, the apparatus is for ion implantation in radio frequency plasma doping (RF-PLAD).

In accordance with further aspects of this particular exemplary embodiment, the aperture-defining device comprises an insert placed under the aperture of the shield ring and above the Faraday cup, wherein the insert is made of a low-etch material.

In accordance with additional aspects of this particular exemplary embodiment, the aperture-defining device comprises a lens cover placed and fitted over the aperture of the shield ring, wherein the lens cover is made of low-etch material.

In accordance with further aspects of this particular exemplary embodiment, the aperture-defining device comprises a spring-loaded device placed under the aperture of the shield ring and above the Faraday cup, wherein the spring-loaded device is made of a low-etch material.

In accordance with other aspects of this particular exemplary embodiment, the shape of the area of at least one aperture comprises at least one of a circular, arc-shaped, slit-shaped, ring-shaped, rectangular, triangular, and elliptical shape.

In accordance with additional aspects of this particular exemplary embodiment, the aperture-defining device comprises at least one of silicon, silicon carbide, carbon, and graphite.

In accordance with another exemplary embodiment, the apparatus may comprise a shield ring positioned on a same plane as and around a periphery of a target wafer, wherein the shield ring comprises a bulk material and has at least one aperture defining an area, a Faraday cup positioned under the at least one aperture, and dose count electronics connected the Faraday cup for calculating ion dose rate.

In accordance with another exemplary embodiment, the apparatus may comprise a shield ring positioned on a same plane as and around a periphery of a target wafer, wherein the shield ring comprises at least one aperture defining an area, a Faraday cup positioned under the at least one aperture, and dose count electronics connected the Faraday cup, wherein the dose count electronics comprise a calculation module for calculating ion dose rate based on correcting for aperture area changes.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 depicts a conventional RF-PLAD ion implantation system.

FIGS. 2A-2B depict a shield ring configuration according to an embodiment of the present disclosure.

FIGS. 3A-3B depict a shield ring configuration according to an embodiment of the present disclosure.

FIGS. 4A-4C depict a shield ring configuration according to an embodiment of the present disclosure.

FIGS. 5A-5C depict a shield ring configuration according to an embodiment of the present disclosure.

FIGS. 6A-6D depict a shield ring configuration according to an embodiment of the present disclosure.

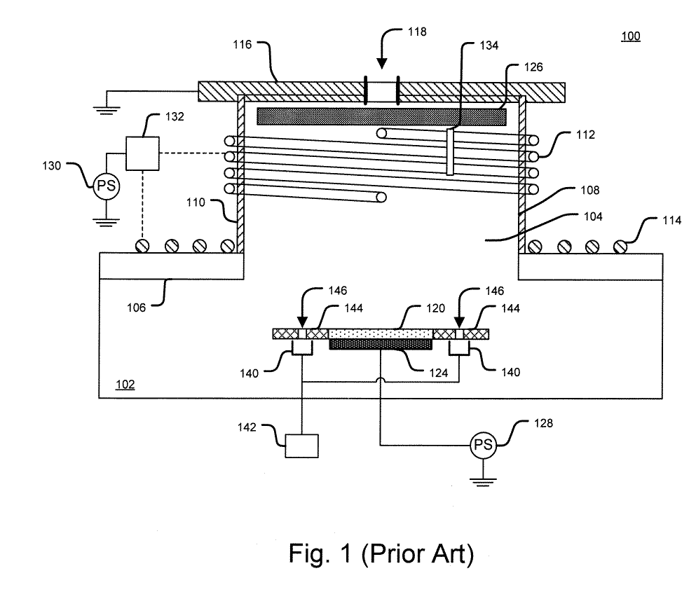

### DETAILED DESCRIPTION OF EXEMPLARY EMBODIMENTS

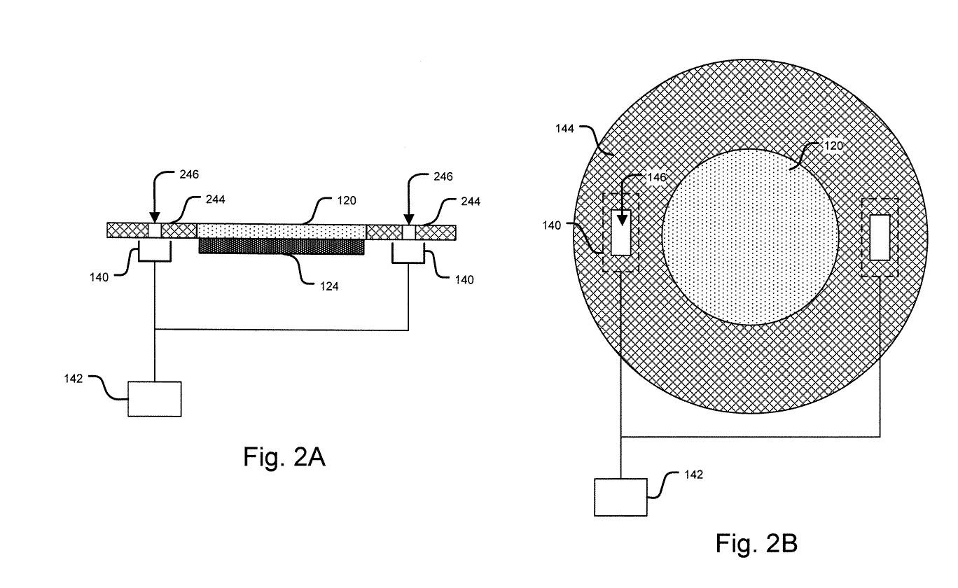

Referring to FIG. 2A, a side view of a shield ring 244 is shown in accordance with an embodiment of the present disclosure. The shield ring 244 may be in the shape of an annulus and may be positioned on a same plane as and around a periphery of the target wafer 120. The shield ring 244 may have one or more shield ring apertures 246 that define an area. One or more Faraday cups 140 may be positioned on a plane below the target wafer 120, under the one or more shield ring apertures 246 and adjacent to the platen (or E-clamp) 124. FIG. 2B depicts a top view of the shield ring 244.

In this embodiment, the area of one or more shield ring apertures 246 is smaller than the opening area of the one or more Faraday cups 140 below the ring 244. In one embodiment, the shield ring 244 may be formed of a thermally and electrically conductive material with a low etch rate, such as aluminum, and coated with silicon (Si), silicon carbide (SiC), carbon (C), graphite, or other similar low-etch coats. In another embodiment, the shield ring 244 may be formed of a bulk (solid) material, such as silicon (Si), silicon carbide (SiC), carbon (C), or graphite. Various types of silicon carbide (SiC) may also be used, e.g., a single crystal silicon, a polycrystalline silicon, etc. In yet another embodiment, the shield ring 244 made of bulk material may be doped for improved resistivity to etching. Coatings and dopings may include a variety of thicknesses depending on the material of the shield ring 244. The process for forming the shield ring 244 from a bulk material may include sintering (heating), chemical vapor deposition (CVD) (layering), and other similar techniques.

An advantage of utilizing a coated shield ring or a shield ring made of bulk material, as described above, may include the ability to create an effective plasma sheath that uniformly extends beyond the wafer edge to maintain normal ion incident angles to the edge of the wafer 120. Another advantage of utilizing a coated shield ring or a shield ring made of bulk material may include the ability to provide and maintain a dimensionally well-defined aperture to allow ion flux to impinge the one or more magnetically suppressed Faraday Cups 140 for accurate measurement of ion flux to the wafer 120. Ultimately, this may provide more precise process control, minimized contamination levels, and reduced consumables cost (e.g., resulting from tedious replacements of expensive shield rings) associated with high volume manufacturing of plasma doping (PLAD) systems.

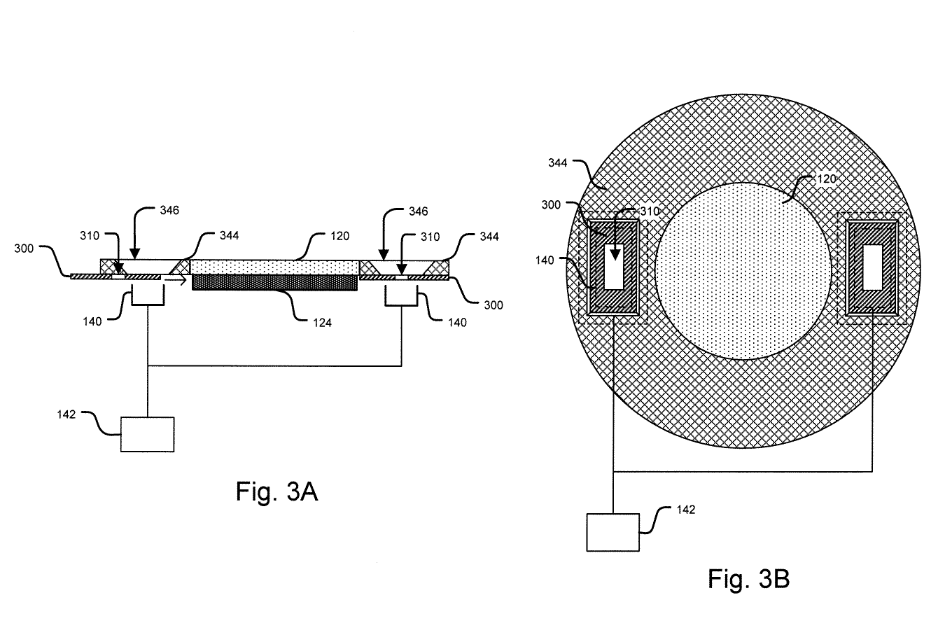

Referring to FIG. 3A, a side view of a shield ring 344 is shown in accordance with an embodiment of the present disclosure. The shield ring 344 may be a conventional shield ring 144 or a shield ring 244 made of low-etch material, as depicted in FIG. 2A-2B. FIG. 3B depicts a top view of the shield ring 144.

In this embodiment, the area of the one or more shield ring apertures 346 may be larger than the opening area of the one or more Faraday cups 140 below the shield ring 344. As discussed above, one reason for an enlarged area of the one or more shield ring apertures 346 may be the result of deterioration (or etching), for example, by NF₃ plasma exposure during plasma doping (PLAD) operation. When the area of the shield ring apertures 146 is larger than the opening area of the one or more Faraday cups 140, dose count electronics (DCE) 142 may inaccurately calculate ion dose rate.

Therefore, a low-etch insert 300 with a small insert aperture 310 may be placed under the one or more enlarged shield ring apertures 346 and above the one or more Faraday cups 140. The small insert aperture 310 of the insert 300 may provide a dimensionally well-defined area for dose count electronics (DCE) 142 to accurately calculate ion dose rate on the target wafer 120. As a result, the replacement interval of the shield ring 344 having the one or more enlarged shield ring apertures 346 may be reduced since the insert 300 includes the defining aperture 310 for ion dose rate measurement. Ultimately, this may provide more precise process control, minimized contamination levels, and reduced consumables cost associated with frequent shield ring replacement during high volume manufacturing of plasma doping (PLAD) systems.

The insert 300 may be formed of a thermally and electrically conductive material with a low etch rate, such as aluminum, and coated with silicon (Si), silicon carbide (SiC), carbon (C), graphite, or other similar low-etch coats. In another embodiment, the low-etch insert 300 may be formed of a bulk (solid) material, such as silicon (Si), silicon carbide (SiC), carbon (C), or graphite. Various types of silicon carbide (SiC) may be used, e.g., a single crystal silicon, a polycrystalline silicon, etc. In yet another embodiment, the insert 300 formed of bulk material may be doped for improved resistivity to etching. Coatings and dopings may include a variety of thicknesses depending on the material of the insert 300. The process for forming the insert 300 from a bulk material may include sintering (heating), chemical vapor deposition (CVD) (layering), and other similar techniques.

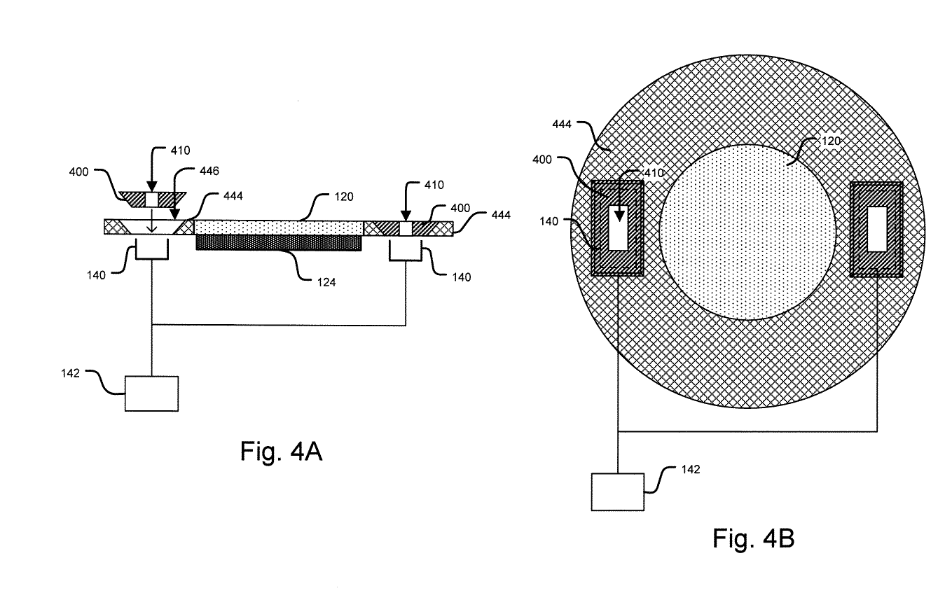

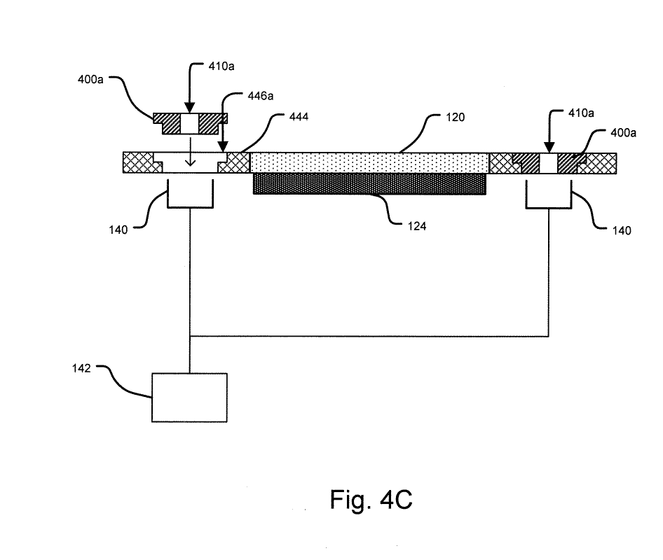

Referring to FIG. 4A, a side view of a shield ring 444 is shown in accordance with an embodiment of the present disclosure. FIG. 4B depicts a top view of the shield ring 444.

In this embodiment, the area of the shield ring apertures 446 may be larger than the opening area of the one or more Faraday cups 140 for similar reasons discussed above. As a result, in this embodiment, a lens cover 400 with a small lens aperture 410 may be placed over the one or more enlarged shield ring apertures 446. The lens cover 400 may have tapered sides that fit against the deteriorated (or etched) portions of the one or more enlarged shield ring apertures 146, which may also be tapered, as depicted in FIG. 4A. The small lens aperture 410 of the lens cover 400 may provide a dimensionally well-defined area for dose count electronics (DCE) 142 to accurately calculate ion dose rate on the target wafer 120.

The lens cover 400 may be formed of a thermally and electrically conductive material with a low etch rate, such as aluminum, and coated with silicon (Si), silicon carbide (SiC), carbon (C), graphite, or other similar low-etch coats. In another embodiment, the lens cover 400 may be formed of a bulk (solid) material, such as silicon (Si), silicon carbide (SiC), carbon (C), or graphite. Various types of silicon carbide (SiC) may be used, e.g., a single crystal silicon, a polycrystalline silicon, etc. In yet another embodiment, the lens cover 400 formed of bulk material may be doped for improved resistivity to etching. Coatings and dopings may include a variety of thicknesses depending on the material of the lens cover 400. The process for forming the lens cover 400 from a bulk material may include sintering (heating), chemical vapor deposition (CVD) (layering), and other similar techniques.

Referring to FIG. 4C, another embodiment of the present disclosure may provide one or more stepped lens covers 400a to be fitted against one or more stepped shield ring apertures 446a. The one or more stepped lens cover 400a are, in most respects, similar to the one or more tapered lens covers 400 as discussed above. However, rather than waiting for the shield ring apertures 446 to be etched and enlarged (to form a tapered portion), the shield ring 444 may include one or more stepped apertures 446 to be fitted with one or more stepped lens covers 400a. This may provide another way to reduce shield ring replacement and associated consumables cost. Other various fitting mechanisms may also be provided.

In another embodiment, a lens cover 400 without a small lens aperture may also be provided. In this example, the lens cover may be used to protect the aperture 146 from etching. Such a lens cover may not be directly used to maintain a well-defined aperture. Instead, the lens cover may preserve unused shield ring apertures on a shield ring having multiple shield ring apertures. This may be useful for indirectly calculating area changes in covered shield ring apertures versus area changes in uncovered shield ring apertures. This process is discussed in further detail below.

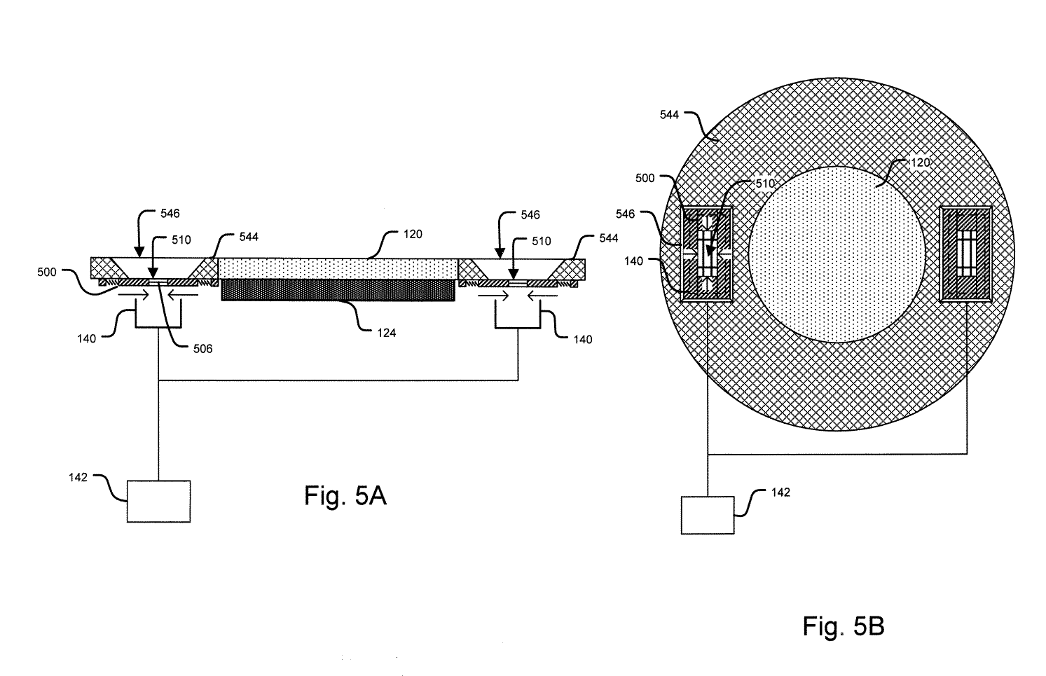

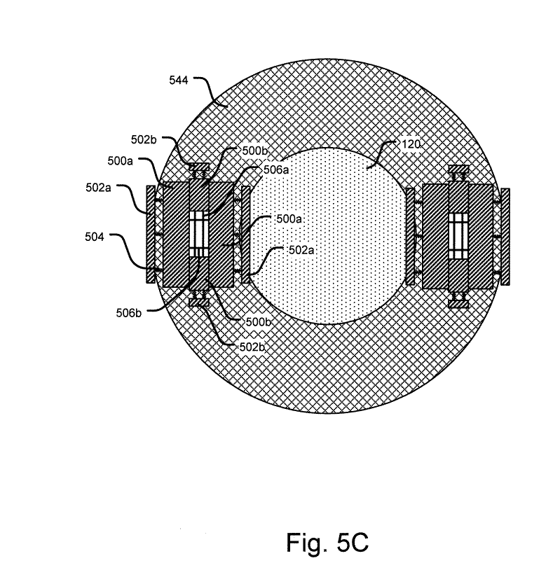

Referring to FIG. 5A, a side view of a shield ring 544 is shown in accordance with an embodiment of the present disclosure. FIG. 5B depicts a top view of the shield ring 544. FIG. 5B depicts a bottom view of the shield ring 544.

In this embodiment, the area of the one or more shield ring apertures 546 may be larger than the area of the one or more Faraday cups 140 for similar reasons discussed above. In one embodiment of the present disclosure, a spring-loaded mechanism 500 with a spring-adjusted aperture 510 may be placed under the one or more enlarged apertures 546 of the shield ring 544 and above the one or more Faraday cups 140. The spring-loaded mechanism 500 may include aperture defining portions 500a, 500b, fixed portions 502a, 502b, springs 504, and aperture bars 506a, 506b, as depicted in FIG. 5C. By placing the spring-loaded mechanism 500 under the one or more shield ring apertures 546, the aperture-defining portions 500a, 500b may define the area of the one or more shield ring apertures 546 during deterioration and/or etching. The aperture bars 506a, 506b may be formed of low-etch, highly resistive material, which serve to define the spring-adjusted aperture 510 dimensions.

The aperture-defining portions 500a, 500b may be formed of a thermally and electrically conductive material with a low etch rate, such as aluminum, and coated with silicon (Si), silicon carbide (SiC), carbon (C), graphite, or other similar low-etch coats. In another embodiment, the aperture-defining portions 500a, 500b may be formed of a bulk (solid) material, such as silicon (Si), silicon carbide (SiC), carbon (C), or graphite. Various types of silicon carbide (SiC) may be used, e.g., a single crystal silicon, a polycrystalline silicon, etc. In yet another embodiment, the lens cover 400 formed of bulk material may be doped for improved resistivity to etching. Coatings and dopings may include a variety of thicknesses depending on the material of the aperture-defining portions 500a, 500b. The process for forming the aperture-defining portions 500a, 500b from a bulk material may include sintering (heating), chemical vapor deposition (CVD) (layering), and other similar techniques.

As the one or more shield ring apertures 546 are etched, the aperture-defining portions 500a, 500b of the spring-loaded mechanism 500 may become exposed to etching as well. Even as the aperture-defining portions 500a, 500b are exposed and etched, the springs 504, which are attached to the fixed portions 502a, 502b, may push the aperture-defining portions 500a, 500b towards the aperture bars 506a, 506b to maintain the size (area) of the one or more shield ring apertures 546. As a result, the spring-loaded aperture 510 may provide a dynamically-dimensioned, well-defined area for dose count electronics (DCE) 142 to accurately calculate ion dose rate on the target wafer 120. Therefore, replacement intervals of shield rings having one or more enlarged apertures may be reduced since the spring-loaded mechanism 500 provides the defining apertures 510 for accurate ion dose rate measurement.

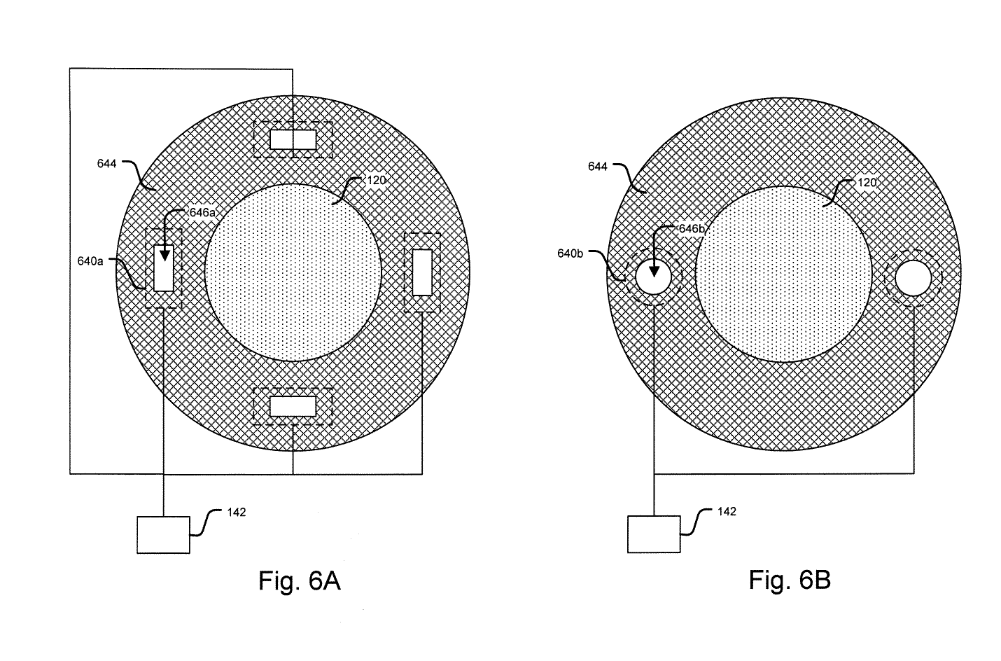

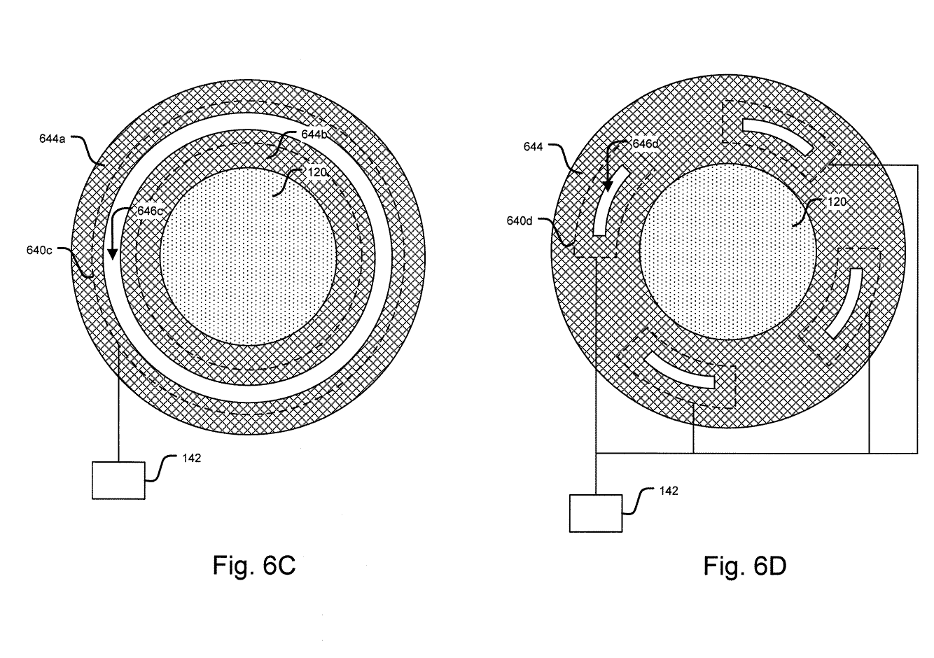

It should be appreciated that while each shield ring, as illustrated above in the embodiments of the present disclosure, is shown with two shield ring apertures each having a rectangular cross section, other numbers, shapes, and sizes of apertures may also be considered. For example, as depicted in FIG. 6A, a shield ring 644 may have one or more apertures 646a, e.g., four apertures. In one embodiment, each aperture 646a may also correspond to one or more separate Faraday cups 140a.

In addition, as depicted in FIGS. 6B and 6D, a shield ring 644 may include one or more shield ring apertures 646 having different shapes, e.g., circular 646b or arc-shaped 646d. Other shapes, such as triangular, elliptical, slit-shaped, etc., may also be provided. Similarly, the one or more Faraday cups 640 may also include different shapes to correspond to the one or more shield ring apertures 646. For example, the one or more Faraday cups 640b may be circular to correspond to the one or more circular apertures 146b or the one or more Faraday cups 640d may be arc-shaped to correspond to the one or more arc-shaped apertures 646d. In another embodiment, a shield ring may include one or more shield ring apertures having a plurality of different shapes. Other variations may also be provided.

Referring to FIG. 6C, the shield ring 644 may include an outer shield ring 644a and an inner shield ring 644b that are separated by a continuous, ring-shaped aperture 646c. In one embodiment, the Faraday cup 640c may also be ring-shaped to correspond to the aperture 646c. A ring-shaped aperture 646c may provide greater accuracy in measuring ion dose rate since incident flux may be averaged over the entire shield ring 644. Other various embodiments may also be provided.

In addition to maintaining a well-defined aperture to improve ion dose rate measurements, embodiments of the present disclosure may also provide processes to correct changes in an area of an aperture caused by etching.

For example, in one embodiment, a process for calculating and correcting for changes in the area of shield ring apertures due to etching may be provided by calculating etch rate. Since etch rate for a given material is predictable in a given set of clean conditions (e.g., power, pressure, flow, DC bias, pulse width frequency, etc.), the etch rate may be inserted into a clean recipe of a calculation module within dose count electronics (DCE) 142 to automatically adjust the area of the aperture during ion dose measurements.

In another embodiment, a process for calculating and correcting for changes in aperture area due to etching may be provided by in-situ optical measurement. In this example, changes in aperture changes may be optically measured and automatically corrected for in the dose count electronics (DCE) 142 during ion dose rate measurements.

In yet another embodiment, a process for calculating and correcting for changes in aperture area due to etching may be provided by using a separate ion source or by using a primary plasma generating source, e.g., a RF source, that is substantially stable. In this example, the known ion source may be used to produce a response in the Faraday counting circuit from which the aperture area could be back-calculated. Calibration using this process may be inserted into the calculation module of the dose count electronics (DCE) 142 and may be done frequently and/or periodically.

In a further embodiment of the disclosure, another process may be provided in the event a primary plasma-generating source is not sufficiently stable to perform the calibration. In this example, a dual-channel dosimetry process may be provided. In one embodiment, a first channel may be used for real-time dosimetry while a second channel may be connected to an aperture that is covered, e.g., by a lens cover, to maintain a constant area only to be removed to perform the calibration. As a result, the value received by the second channel during calibration may be compared to the first channel so that the difference and changes in area may be calculated.

In another embodiment, a first channel may be connected to an aperture (or a set of apertures) having a particular physical geometry, e.g., circular. A second channel may be connected to another aperture (or set of apertures) having a different physical geometry, e.g., slit-shaped. As the apertures etch in response to plasma exposure, the ratio of perimeter to area may change differently for apertures connected to the first channel when compared to apertures connected to the second channel. As a result, the difference in ratio may be inserted into the dose count electronics (DCE) 142, for example, and used to calculate the actual area of each etched aperture for improved ion dose rate measurement.

It should be appreciated that while embodiments of the present disclosure are directed to confining secondary electrons in RF-PLAD, other implementations may be provided as well. For example, a technique for confining of secondary electrons may apply to plasma-based ion implantation systems, such as glow discharge plasma doping (GD-PLAD) system. In this example, an additional source of plasma, such as a hollow cathode, may also be provided.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure can be beneficially implemented in any number of environments for any number of purposes. Accordingly, the claims set forth below should be construed in view of the full breadth and spirit of the present disclosure as described herein.

1. An apparatus for plasma-based ion implantation, the apparatus comprising:
a shield ring positioned on a same plane as and around a periphery of a target wafer, wherein the shield ring comprises an aperture-defining device for defining an area of at least one aperture;
a Faraday cup positioned under the at least one aperture; and
dose count electronics connected the Faraday cup for calculating ion dose rate.

2. The apparatus of claim 1, wherein the apparatus is for ion implantation in glow discharge (GD) PLAD.

3. The apparatus of claim 1, wherein the apparatus is for ion implantation in radio frequency (RF) PLAD.

4. The apparatus of claim 1, wherein the aperture-defining device comprises at least one of silicon, silicon carbide, carbon, and graphite.

5. The apparatus of claim 1, wherein the aperture-defining device comprises an insert placed under the aperture of the shield ring and above the Faraday cup, wherein the insert is made of a low-etch material.

6. The apparatus of claim 1, wherein the aperture-defining device comprises a lens cover placed and fitted over the aperture of the shield ring, wherein the lens cover is made of low-etch material.

7. The apparatus of claim 1, wherein the aperture-defining device comprises a spring-loaded device placed under the aperture of the shield ring and above the Faraday cup, wherein the spring-loaded device is made of a low-etch material.

8. The apparatus of claim 1, wherein the shape of the area of at least one aperture comprises at least one of a circular, arc-shaped, slit-shaped, ring-shaped, rectangular, triangular, and elliptical shape.

9. An apparatus for plasma-based ion implantation, the apparatus comprising:
a shield ring positioned on a same plane as and around a periphery of a target wafer, wherein the shield ring comprises a bulk material and has at least one aperture defining an area;
a Faraday cup positioned under the at least one aperture; and
dose count electronics connected the Faraday cup for calculating ion dose rate.

10. The apparatus of claim 9, wherein the bulk material comprises at least one of silicon, silicon carbide, carbon, and graphite.

11. An apparatus for plasma-based ion implantation, the apparatus comprising:
a shield ring positioned on a same plane as and around a periphery of a target wafer, wherein the shield ring comprises at least one aperture defining an area;
a Faraday cup positioned under the at least one aperture; and
dose count electronics connected the Faraday cup, wherein the dose count electronics comprise a calculation module for calculating ion dose rate based on correcting for aperture area changes.

12. The apparatus of claim 11, wherein the calculation module calculates ion dose rate based on correcting for aperture area changes.

13. The apparatus of claim 12, wherein the calculation module corrects for aperture area changes based on etch rate information of the shield ring.

14. The apparatus of claim 12, wherein the calculation module corrects for aperture area changes based on in-situ optical measurements of aperture area changes.

15. The apparatus of claim 12, wherein the calculation module corrects for aperture area changes based on a separate ion source.

16. The apparatus of claim 12, wherein the calculation module corrects for aperture area changes based on a substantially stable primary plasma source.

17. The apparatus of claim 12, wherein the calculation module corrects for aperture area changes based on dual-channel calibration.

18. The apparatus of claim 17, wherein the dual-channel calibration comprises a first channel and a second channel.

19. The apparatus of claim 18, wherein the first channel is connected to at least one aperture for real-time dosimetry and the second channel is connected to at least one aperture that is covered, such that the measurement values received by the second channel, when uncovered, and compared to the first channel are used in calculating ion dose rate.

20. The apparatus of claim 18, wherein the first channel is connected to at least one aperture having a first geometry and the second channel is connected at least one aperture having a second geometry, such that measurement information a first ratio of perimeter to area for the at least one apertures connected to the first channel and a second ratio of perimeter to area for the at least one apertures connected to the second channel are compared and used in calculating ion dose rate.

21. A method for maintaining an area of at least one aperture for plasma-based ion implantation, the method comprising:
positioning a shield ring on a same plane as and around a periphery of a target wafer, wherein the shield ring comprises an aperture-defining device for defining an area of at least one aperture over a Faraday cup for use calculating ion dose rate.

22. A method for maintaining an area of at least one aperture for plasma-based ion implantation, the method comprising:
positioning a shield ring on a same plane as and around a periphery of a target wafer, wherein the shield ring is made of a low-etch, bulk material and has at least one aperture that defines an area over a Faraday cup for use calculating ion dose rate.

23. A method for plasma-based ion implantation, the method comprising:
calculating ion dose rate based at least in part on correcting for aperture area changes, wherein the aperture area changes are based on aperture area change information.

24. The method of claim 23, wherein the aperture area change information comprises at least one of etch rate information, in-situ optical measurement information of aperture area changes, information based on a separate ion source, information based on a substantially stable plasma source, and information based on a dual-channel calibration.
